(19) United States
(12) Patent Application Publication
(10) Pub. No.: US 2025/0365848 A1
(43) Pub. Date: Nov. 27, 2025

(54) ELECTRONIC DEVICE AND HEAT DISSIPATION COMPONENT THEREOF

(71) Applicant: LITE-ON TECHNOLOGY CORPORATION, Taipei (TW)

(72) Inventors: Yi-Jen LU, Taipei (TW); Yu-Hsuan CHANG, Taipei (TW); Chung-Ting CHENG, Taipei (TW); Che-Han LIN, Taipei (TW)

(21) Appl. No.: 19/055,546

(22) Filed: Feb. 18, 2025

(30) Foreign Application Priority Data
May 23, 2024 (CN) 202421133656.6

(51) Int. Cl. H05K 1/02; G06F 1/20; H05K 1/18; H05K 7/14; H05K 7/20

(52) U.S. Cl. CPC H05K 1/0203; G06F 1/20; H05K 1/181; H05K 7/20172; H05K 7/1427

(57) ABSTRACT

An electronic device includes a circuit board, a heat dissipation component and an electronic component. The heat dissipation component is disposed on the circuit board and includes a support segment and an extension segment. The extension segment is connected to the support segment. The electronic component is disposed in the support segment. The extension segment and the support segment are not parallel.

This application claims the benefit of People's Republic of China application Serial No. 202421133656.6, filed on May 23, 2024, the subject matter of which is incorporated herein by reference.

### BACKGROUND OF THE INVENTION

### Field of the Invention

The invention relates in general to an electronic device and a heat dissipation component thereof.

### Description of the Related Art

Conventional electronic device includes at least one electronic component. The operation of electronic component inevitably generates heat. Therefore, how to dissipate heat is one of the goals of industry players in this technical field.

### SUMMARY OF THE INVENTION

According to an embodiment of the present invention, an electronic device is provided. The electronic device includes a circuit board, a heat dissipation component and an electronic component. The heat dissipation component is disposed on the circuit board and includes a support segment and a first extension piece. The first extension piece is connected to the support segment. The electronic component is disposed on the support segment. The first extension piece and the support segment are not parallel.

According to another embodiment of the present invention, a heat dissipation component is provided. The heat dissipation component includes a support segment, a first extension piece and a second extension piece. The first extension piece has a first end and a second end, wherein the first end of the first extension piece is connected to the support segment. The second extension piece has a first end and a second end, wherein the first end of the second extension piece is connected to the second end of the first extension piece, an extension direction of the first end of the first extension piece toward the second end of the first extension piece is different from an extension direction of the first end of the second extension piece toward the second end of the second extension piece.

According to another embodiment of the present invention, a heat dissipation component is provided. The heat dissipation component includes a support segment, a first extension piece and a second extension piece. The first extension piece is connected to the support segment and has an upper surface. The second extension piece is connected to the first extension piece and has a lower surface. A gap is formed between the upper surface of the first extension piece and the lower surface of the second extension piece.

According to another embodiment of the present invention, an electronic device is provided. The electronic device includes a casing, a circuit board, a heat dissipation component and an electronic component. The casing has at least one opening. The circuit board is disposed within the casing. The heat dissipation component is disposed on the circuit board, corresponding to the at least one opening, and incudes a support segment, a first extension piece and a second extension piece. The first extension piece has a first end and a second end, wherein the first end of the first extension piece is connected to the support segment. The second extension piece has a first end and a second end, wherein the first end of the second extension piece is connected to the second end of the first extension piece, an extension direction of the first end of the first extension piece toward the second end of the first extension piece is different from an extension direction of the first end of the second extension piece toward the second end of the second extension piece. The electronic component engaged with the support segment and electrically connected to the circuit board.

According to another embodiment of the present invention, an electronic device is provided. The electronic device includes a casing, a circuit board, a heat dissipation component and an electronic component. The casing has at least one opening. The circuit board is disposed within the casing. The heat dissipation component is disposed on the circuit board and includes a support segment and a first extension piece. The support segment protrudes from the circuit board. The first extension piece is connected to the support segment and extends toward a side of the support segment. The electronic component is disposed on the support segment. The first extension piece has an extension width greater than or equal to a width of the electronic component.

The above and other aspects of the invention will become better understood with regard to the following detailed description of the preferred but non-limiting embodiment(s). The following description is made with reference to the accompanying drawings.

### BRIEF DESCRIPTION OF THE DRAWINGS

FIG. 1A shows an assembly diagram of the electronic device according to an embodiment of the present invention;

FIG. 1B shows a schematic diagram of an exploded view of the electronic device in FIG. 1A;

FIG. 2 shows a schematic diagram of an exploded view of a heat dissipation component, a first electronic component and a second electronic component;

FIG. 3 shows a schematic diagram of the heat dissipation component in FIG. 2;

FIG. 4 shows a schematic diagram of a cross-sectional view in a direction 4-4′;

FIG. 5 shows a schematic diagram of an electronic device according to another embodiment of the present invention;

FIG. 6 shows a schematic diagram of a heat dissipation component according to another embodiment of the present invention;

FIG. 7 shows a schematic diagram of a heat dissipation component according to another embodiment of the present invention;

FIG. 8A shows a schematic diagram of a heat dissipation component according to another embodiment of the present invention;

FIG. 8B shows a schematic diagram of a heat dissipation component according to another embodiment of the present invention;

FIG. 9 shows a schematic diagram of a heat dissipation component according to another embodiment of the present invention;

FIG. 10 shows a schematic diagram of a heat dissipation component according to another embodiment of the present invention; and

FIG. 11 shows a schematic diagram of a heat dissipation component according to another embodiment of the present invention.

### DETAILED DESCRIPTION OF THE INVENTION

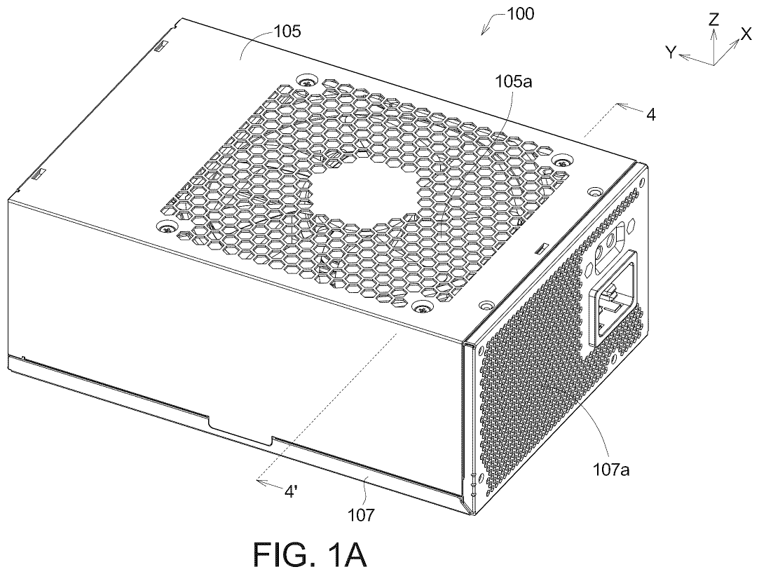

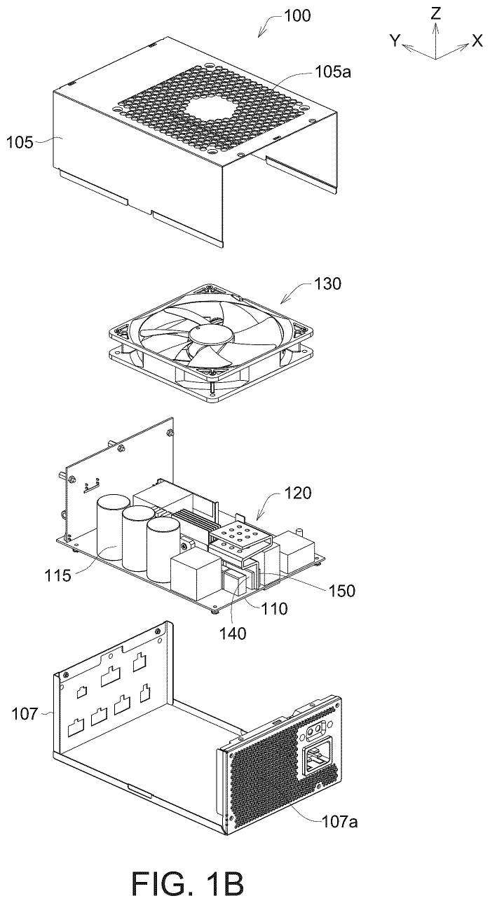

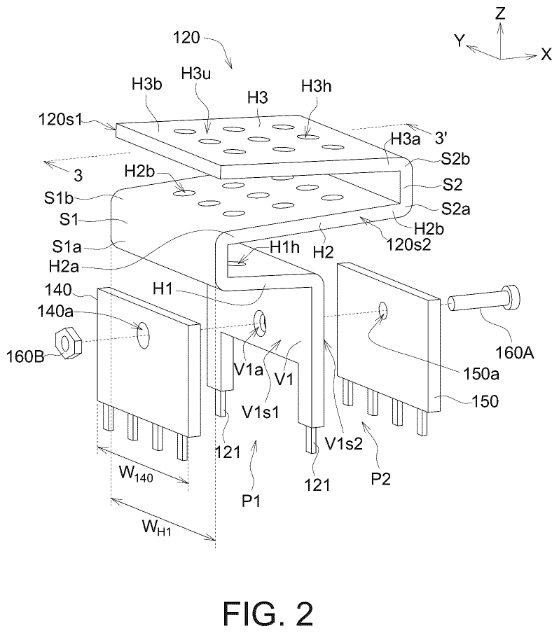

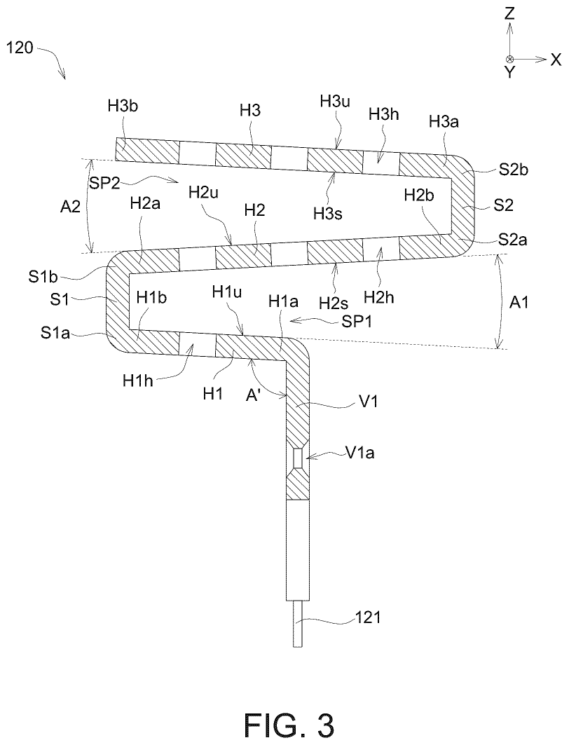

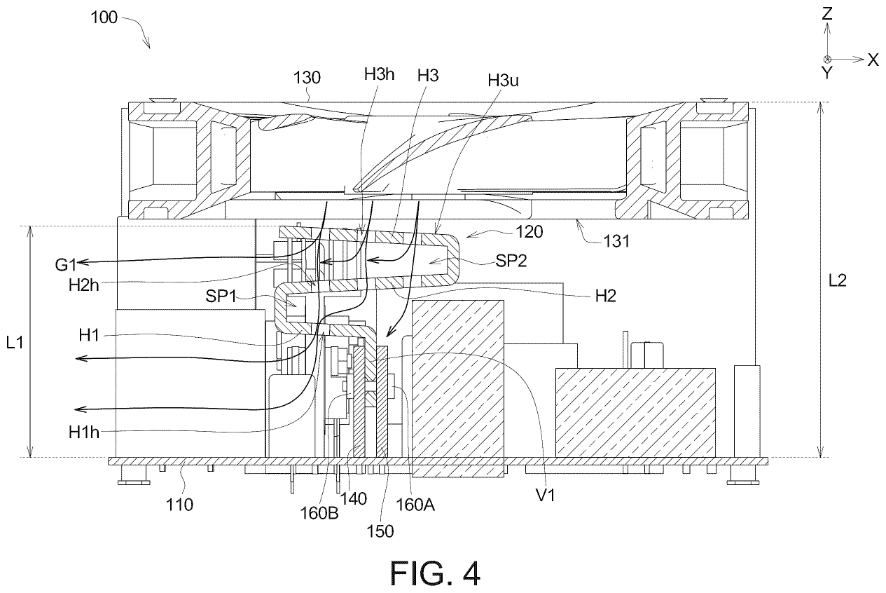

Referring to FIGS. 1A to 4, FIG. 1A shows an assembly diagram of the electronic device 100 according to an embodiment of the present invention, FIG. 1B shows a schematic diagram of an exploded view of the electronic device 100 in FIG. 1A, FIG. 2 shows a schematic diagram of an exploded view of a heat dissipation component 120, a first electronic component 140 and a second electronic component 150, FIG. 3 shows a schematic diagram of the heat dissipation component 120 in FIG. 2, and FIG. 4 shows a schematic diagram of a cross-sectional view in a direction 4-4′ (the casing is not shown). The electronic device 100 is, for example, a power supply unit (PSU), a power storage unit, an operation unit, or other types of electronic products. The electronic device 100 may be applied to a desktop computer, an industrial computer, a server, a charging equipment or a consumer electronic product.

As shown in FIGS. 1A and 1B, the electronic device 100 includes a casing, a circuit board 110, at least one electronic component 115, a heat dissipation component 120, a cooling assembly 130, a first electronic component 140, a second electronic component 150 and a first fixing component 160A and a second fixing component 160B. In an embodiment, the casing includes an upper shell 105 and a lower shell 107 that may be assembled, snapped or connected, the circuit board 110, the electronic components 115, the heat dissipation component 120, the cooling assembly 130, the first electronic component 140, the second electronic component. 150, the first fixing component 160A and the second fixing component 160B may be disposed on the lower shell 107 and are surrounded by the upper shell 105 and the lower shell 107. The electronic component 115 is a capacitor, for example. However, in another embodiment, other electronic components 115 are, for example, connectors, sockets, resistors, chips and/or inductors. In the present embodiment, the cooling assembly 130 and the heat dissipation component 120 overlap along Z-axis, wherein Z-axis is, for example, a height direction or a vertical direction of the electronic device 100.

As shown in FIGS. 2 and 3, the heat dissipation component 120 is disposed on the circuit board 110. The heat dissipation component 120 includes an insertion portion 121, a support segment V1, a first extension piece H1, a second extension piece H2, a third extension piece H3, a first connection segment S1 and a second connection segment S2. The first extension piece H1 is connected to the support segment V1. The first extension piece H1 and the support segment V1 are not parallel; that is, an extension of the first extension piece H1 and an extension of the support segment V1 would intersect. The first electronic component 140 is engaged with or disposed on the support segment V1. As a result, the heat dissipation component 120 may quickly conduct the heat of the first electronic component 140 to the air.

As shown in FIGS. 2 and 3, due to the shape of the heat dissipation component 120 of the embodiment of the present invention, it is especially suitable for forming by stamping or bending. In an embodiment, the material of the heat dissipation component 120 may be selected from the aluminum specifications of JIS 6063, JIS 1100 or a combination thereof. Alternatively, the heat dissipation component 120 may be formed of aluminum recycled products, such as pre-consumer recycled aluminum, industrial scraps and/or defective products. Alternatively, the heat dissipation component 120 may also be formed of other materials, such as copper, iron, silver, gold or combinations thereof. For the heat dissipation component 120 formed by stamping or bending, its material is not limited to aluminum that meets the specification, and may also be selected from the aforementioned recycled products. In terms of the manufacturing process, a sheet or a plate may be stamped, bent, or a combination thereof to form the heat dissipation component 120. In terms of structure, at least two of the insertion portion 121, the support segment V1, the first extension piece H1, the second extension piece H2, the third extension piece H3, the first connection segment S1 and the second connection segment S2 may be integrated into one piece. In addition, the heat dissipation component 120 and the circuit board 110 may be electrically isolated. In other words, the heat dissipation component 120 simply provides a heat dissipation effect and has no circuit function. In another embodiment, the heat dissipation component 120 may be electrically connected to a ground potential (not shown), so that the heat dissipation component 120 becomes a ground component.

As shown in FIGS. 2 and 3, the insertion portion 121 of the heat dissipation component 120 is connected to a bottom surface of the support segment V1 so as to be disposed (for example, inserted) in the circuit board 110. The insertion portion 121 may be welded to the circuit board 110 to fix a relative position between the heat dissipation component 120 and the circuit board 110, as shown in FIG. 1B. As shown in FIG. 4, after the heat dissipation component 120 is disposed on the circuit board 110, the support segment V1 protrudes from the circuit board 110.

As shown in FIGS. 2 and 3, the first extension piece H1 is, for example, a transverse segment extending toward a side of the support segment V1 (for example, a first side P1), and the first extension piece H1 is connected to the support segment V1. For example, the first extension piece H1 has a first end H1a and a second end H1b, wherein the first end H1a of the first extension piece H1 is connected to an end of the support segment V1. In addition, the first extension piece H1 and the support segment V1 are not parallel to each other. For example, there is an angle A′ between the first extension piece H1 and the support segment V1, wherein the angle A′ is, for example, an obtuse angle, a right angle or an acute angle. In addition, the extension width WH1 of the first extension piece H1 is greater than or equal to the width W140 of the first electronic component 140, and thus it may increase a contact area between the first extension piece H1 and the first electronic component 140. As a result, the heat dissipation efficiency may be increased. In another embodiment, an extension width (for example, parallel to the extension width WH1) of the second extension piece H2 is equal, less than or greater than the extension width WH1 of the first extension piece H1.

As shown in FIGS. 2 and 3, the second extension piece H2 has a portion facing the first extension piece H1. The second extension piece H2 is, for example, a transverse segment extending to another side of the support segment V1 (for example, a second side P2 opposite to the first side P1), and the second extension piece H2 connects the first extension piece H1 through the first connection segment S1. For example, the second extension piece H2 has a first end H2a and a second end H2b, and the first connection segment S1 has a first connection end S1a and a second connection end S1b, wherein the first end H2a of the second extension piece H2 is connected to the second end H1b of an extension piece H1, the first connection end S1a of the first connection segment S1 is connected to the second end H1b of an extension piece H1, and the second connection end S1b of the first connection segment S1 is connected to the first end H2a of the second extension piece H2. In the present embodiment, an extension direction of the first end H1a of the first extension piece H1 toward the second end H1b of the first extension piece H1 is different from an extension direction of the first end H2a of the second extension piece H2 toward the second end H2b of the second extension piece H2.

As shown in FIGS. 2 and 3, the third extension piece H3 is, for example, a transverse segment extending toward the first side P1 of the support segment V1, and the third extension piece H3 is connected to the second extension piece H2 through the second connection segment S2. For example, the third extension piece H3 has a first end H3a and a second end H3b, and the second connection segment S2 has a first connection end S2a and a second connection end S2b, wherein the first end H3a of the third extension piece H3 is connected to the second end H2b of the second extension piece H2, the second end H3b of the third extension piece H3 is a free end (not directly connected to other extension piece or connection segment), and the first connection end S2a of the second connection segment S2 is connected to the second end H2b of the second extension piece H2, and the second connection end S2b of the second connection segment S2 is connected to the first end H3a of the third extension piece H3.

The “connection” in this article refers to a “direct connection” or an “indirect connection”, wherein “direct connection” is, for example, two components connected to each other without an intermediate component, and “indirect connection” is, for example, a connection between two components connected to each other through another component.

Two adjacent extension pieces respectively have an upper surface and a lower surfaces opposite to the upper surface, wherein the upper and lower surfaces may form an airflow space (or gap). For example, as shown in FIGS. 2 and 3, the first extension piece H1 has an upper surface H1u. The second extension piece H2 is connected to the first extension piece H1 and has a lower surface H2s. A first airflow space SP1 (or gap) is formed between the upper surface H1u of the first extension piece H1 and the lower surface H2s of the second extension piece H2. For another example, the second extension piece H2 has an upper surface H2u, and the third extension piece H3 has a lower surface H3s, wherein a second airflow space SP2 (or gap) is formed between the upper surface H2u of the second extension piece H2 and the lower surface H3s of the third extension piece H3.

In addition, there is an airflow space (or gap) between two adjacent extension pieces, and the airflow space may be provided corresponding to the opening of the casing. For example, as shown in FIG. 3, the first airflow space SP1 (or gap) is formed between the upper surface H1u of the first extension piece H1 and the lower surface H2s of the second extension piece H2, which may correspond to an opening 107a (the opening 107a is shown in FIG. 1B) of the lower surface of the lower shell 107 so that the airflow flows through the airflow space to flow out of the lower shell 107 from the opening 107a by the shortest path. Similarly, as shown in FIG. 3, a second airflow space SP2 (or gap) is formed between the upper surface H2u of the second extension piece H2 and the lower surface H3s of the third extension piece H3, which may correspond to the opening 107a (the opening 107a is shown in FIG. 1B) of the lower shell 107 so that the airflow flowing through the airflow space flows out of the lower shell 107 from the opening 107a by the shortest path. The opening 107a is, for example, a through hole.

At least one extension piece may have at least one through hole to provide a passage for air flow passing through the extension piece. For example, as shown in FIGS. 2 and 3, the first extension piece H1 has at least one through hole H1h. The airflow may enter the space below the first extension piece H1 or enter the first airflow space SP1 through the through hole H1h. For another example, the second extension piece H2 has at least one through hole H2h, and the airflow may enter the space below the second extension piece H2 or enter the second airflow space SP2 through the through hole H2h. For another example, the third extension piece H3 has at least one through hole H3h, and the airflow may enter the space below the third extension piece H3 or enter the second airflow space SP2 through the through hole H3h. In addition, the through hole H1h of the first extension piece H1 may be disposed corresponding to the opening of the casing. For example, the through hole H1h of the first extension piece H1 may be disposed corresponding to the opening 105a (the opening 105a is shown in FIG. 1B) of the upper shell 105. Similarly, the through hole H2h of the second extension piece H2 may be disposed corresponding to the opening of the casing. For example, the through hole H2h of the second extension piece H2 may be disposed corresponding to the opening 105a of the upper shell 105. The opening 105a is, for example, a through hole.

In addition, the heat dissipation component 120 further has a first lateral surface 120s1 and a second lateral surface 120s2 opposite to the first lateral surface 120s1, wherein the first lateral surface 120s1 and the second lateral surface 120s2 may connect the upper surface and the lower surface of each extension piece. The airflow space between two adjacent extension pieces may extend to the second lateral surface 120s2 from the first lateral surface 120s1.

As shown in FIGS. 2 and 3, the connection segment connecting two adjacent extension pieces may be a straight segment. For example, the first connection segment S1 connecting the first extension piece H1 with the second extension piece H2 is a straight segment, and the second connection segment S2 connecting the second extension piece H2 and the third extension piece H3 is, for example, a straight segment. In another embodiment, if the length of the connection segment is short, the connection segment connecting two adjacent extension pieces may be an arc segment. In other embodiments, the connection segment of the heat dissipation component 120 may be omitted. In this example, two adjacent extension pieces may be directly connected, so that the two adjacent extension pieces are like two edges of a triangle. In an embodiment, when two adjacent extension pieces are connected and are non-parallel to each other, the connection segment connects two adjacent extension pieces non-perpendicularly. When two adjacent extension pieces are parallel, the connection segment may vertically connect the two adjacent extension pieces.

An airflow space is formed among two adjacent extension pieces and the connection segment. For example, as shown in FIGS. 2 and 3, the first airflow space SP1 is formed among the first extension piece H1, the second extension piece H2 and the first connection segment S1, and the second airflow space SP2 is formed among the second extension piece H2, the third extension piece H3 and the second connection segment S2.

As shown in FIGS. 2 and 3, there is an included angle between two adjacent extension pieces. For example, a first included angle A1 is included between the first extension piece H1 and the second extension piece H2, and a second included angle A2 is included between the second extension piece H2 and the third extension piece H3. The first included angle A1 and/or the second included angle A2 is, for example, an acute angle, which may be greater than or equal to 0 degrees and less than or equal to 90 degrees. In an embodiment, the first included angle A1 and/or the second included angle A2 ranges between 3 degrees and 60 degrees. As a result, the included angle may help the heat dissipation component 120 to be easily demolded during the manufacturing process (for example, it is easy to be demolded from a bending mold or a stamping mold). In another embodiment, if the release property is not considered, the first included angle A1 and/or the second included angle A2 may be an obtuse angle or a right angle.

As shown in FIGS. 2 and 4, the support segment V1 has a first surface V1s1 and a second surface V1s2 that are opposite to the first surface V1s1, and the first electronic component 140 and the second electronic component 150 are respectively disposed on the first surface V1s1 and the second surface V1s2. The first extension piece H1 is connected to an end of the support segment V1 and is located above or directly above or covers the first electronic component 140. The first electronic component 140 could be covered by the first extension piece H1. The through hole H1h of the first extension piece H1 may be at a position corresponding to the first electronic component 140. For example, the through hole H1h of the first extension piece H1 may be located above the first electronic component 140. As a result, the airflow of the cooling assembly 130 may flow to the first electronic component 140 through the through hole H1h to cool the first electronic component 140. In another embodiment, the through hole H1h and the first electronic component 140 may overlap along Z-axis, so that the air flow path between the through hole H1h and the first electronic component 140 is shorter or the shortest for increasing the cooling efficiency. In addition, the second extension piece H2 is located above or directly above the second electronic component 150. The second electronic component 150 could be covered by the second extension piece H2. The through hole H2h of the second extension piece H2 at a position corresponding to the second electronic component 150. For example, the through hole H2h of the second extension piece H2 is located above the second electronic component 150. As a result, the airflow of the cooling assembly 130 may flow to the second electronic component 150 through the through hole H2h, so as to cool the second electronic component 150. In another embodiment, the through hole H2h and the second electronic component 150 may overlap along Z-axis, so that the air flow path between the through hole H2h and the second electronic component 150 is shorter or the shortest for increasing the cooling efficiency.

As shown in FIGS. 2 and 4, the third extension piece H3 is located above the second extension piece H2. In an embodiment, the through hole H3h of the third extension piece H3 and the through hole H2h of the second extension piece H2 may overlap along Z-axis, so that the air flow path between the through hole H3h of the third extension piece H3 and the through hole H2h of the through hole H2 is shorter or the shortest for increasing the cooling efficiency. In an embodiment, the through hole H1h of the first extension piece H1, the through hole H2h of the second extension piece H2 and the through hole H3h of the third extension piece H3 may overlap along Z-axis, so that the air flow path between through hole H1h of the first extension piece H1, the through hole H2h of the second extension piece H2 and the through hole H3h of the third extension piece H3 is shorter or the shortest for increasing the cooling efficiency, and the airflow of the cooling assembly 130 may flow along a straight path (with small wind resistance) to increase the cooling efficiency. In addition, For example, the through hole H3h of the third extension piece H3 may be disposed corresponding to the opening 105a (the opening 105a is shown in FIG. 1B) of the upper shell 105.

As shown in FIGS. 1B and 4, in the present embodiment, the cooling assembly 130 may be disposed above the heat dissipation component 120. In an embodiment, the cooling assembly 130 may be, for example, a fan disposed directly above the heat dissipation component 120 to direct airflow. The cooling assembly 130 with a larger coverage substantially overlaps the support segment V1 or the first extension piece H1 of the heat dissipation component 120 along a direction (for example, Z-axis). The cooling assembly 130 has an air outlet 131 that overlaps the upper surface (for example, the upper surface H3u) of the topmost extension piece (for example, the third extension piece H3) of the heat dissipation component 120 along Z-axis. As a result, the airflow G1 flowing out from the air outlet 131 of the cooling assembly 130 may flow (directly or indirectly) to the upper surface (for example, the upper surface H3u) of the topmost extension piece (for example, the third extension piece H3) of the heat dissipation component 120. In an embodiment, an outer frame of the cooling assembly 130 may also have a protruding structure corresponding to the upper shell 105 for reducing the gap between the cooling assembly 130 and an inner surface of the upper shell 105, thereby optimizing the cooling air flow path and improving the overall heat dissipation effect.

The first electronic component 140 and/or the second electronic component 150 are, for example, heat sources in the electronic device 100. In an embodiment, the first electronic component 140 and/or the second electronic component 150 are, for example, semiconductor components, which may be respectively a rectifier, a MOSFET (Metal-Oxide-Semiconductor Field-Effect Transistor), integrated circuit (IC), a magnetic component, a capacitor, a dual in-line package (DIP) and/or other surface mount devices (SMD), etc.

As shown in FIGS. 2 and 4, the first fixing component 160A and the second fixing component 160B may fix a relative position of the heat dissipation component 120 and the electronic component. For example, the support segment V1 has a through hole V1a, the first electronic component 140 has a through hole 140a, the second electronic component 150 has a through hole 150a, and the first fixing component 160A may pass through the through hole 150a, the through hole V1a, and the through hole 140a, and combined with the second fixing component 160B to fix a relative positions among the heat dissipation component 120, the first electronic component 140 and the second electronic component 150. In an embodiment, the first fixing component 160A is, for example, a bolt, and the second fixing component 160B is, for example, a nut.

In addition to using the first fixing component 160A and/or the second fixing component 160B, in some embodiments, the electronic components may be fixed to the heat dissipation component 120 through other methods. For example, thermally conductive adhesive materials are respectively provided on two sides of the support segment V1 of the heat dissipation component 120. The first electronic component 140 and the second electronic component 150 may be attached to the entire surface of the heat dissipation component 120 through the thermally conductive adhesive material for fixing effect and/or the uniform heat dissipation effect.

As shown in FIG. 4, the heat dissipation component 120 has a first height L1, the electronic device 100 has a second height L2, wherein a ratio of the first height L1 of the heat dissipation component 120 to the second height L2 of the electronic device 100 ranges, for example, between 0.3 and 0.85, but it may also be lower or higher. However, the embodiment of the present invention does not limit the ratio of the first height L1 to the second height L2, as long as the heat dissipation component 120 does not interfere with other components of the electronic device 100. In an embodiment, the ratio of the first height L1 to the second height L2 may range between 0.4 and 0.6 to provide better airflow space and heat dissipation effect. In addition, the number of at least one extension piece of the heat dissipation component 120 depends on the height of the support segment V1, and the height of the support segment depends on the height of the first electronic component 140 and the height of the second electronic component 150, which is not limited in the embodiment of the present invention.

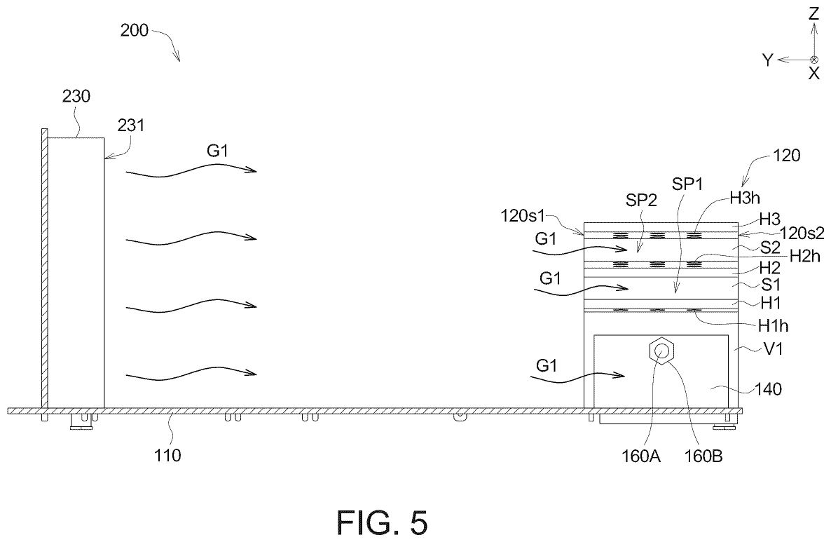

Referring to FIG. 5, FIG. 5 shows a schematic diagram of an electronic device 200 according to another embodiment of the present invention. The electronic device 200 is, for example, a power supply unit or other types of electronic products.

As shown in FIG. 5, the electronic device 200 includes the aforementioned causing, the circuit board 110, at least one third electronic component 115 (not shown), the heat dissipation component 120, a cooling assembly 230, the first electronic component 140, the second electronic component 150 (not shown), the first fixing component 160A and the second fixing component 160B. The heat dissipation component 120 is disposed on the circuit board 110. The heat dissipation component 120 includes the insertion portion 121, the support segment V1, the first extension piece H1, the second extension piece H2, the third extension piece H3, the first connection segment S1 and the second connection segment S2. The first extension piece H1 is connected to the support segment V1. The first extension piece H1 and the support segment V1 are not parallel to each other. The first electronic component 140 is disposed on the support segment V1. As a result, the heat dissipation component 120 may quickly conduct the heat of the first electronic component 140 to the air.

The electronic device 200 includes the technical features the same as or similar to that of the aforementioned electronic device 100, and at least one difference is that the arrangement position of the cooling assembly 230 of the electronic device 200 is different from the arrangement position of the cooling assembly 130 of the electronic device 100. In the present embodiment, the cooling assembly 230 and the heat dissipation component 120 overlap along Y-axis, wherein Y-axis is, for example, a horizontal direction of the electronic device 100.

As shown in FIG. 5, the cooling assembly 230 has an air outlet 231, and the air outlet 231 overlaps with the first lateral surface 120s1 of the heat dissipation component 120 along X-axis. As a result, the airflow G1 flowing out from the air outlet 231 of the cooling assembly 230 may flow (directly or indirectly) to the first lateral surface 120s1 of the heat dissipation component 120 and into the airflow space (for example, SP1 and SP2) between two adjacent extension pieces. In addition, similar to the aforementioned electronic device 100, the through hole H1h of the first extension piece H1 may be disposed corresponding to the opening 105a of the upper shell 105 (the opening 105a is shown in FIG. 1B). Similarly, the through hole H2h of the second extension piece H2 may be disposed corresponding to the opening of the casing. For example, the through hole H2h of the second extension piece H2 may be disposed corresponding to the opening 105a of the upper shell 105. The through hole H3h of the third extension piece H3 may be disposed corresponding to the opening of the casing. For example, the through hole H3h of the third extension piece H3 may be disposed corresponding to the opening 105a of the upper shell 105 (the opening 105a is shown in FIG. 1B). The opening 105a is, for example, a through hole. In addition, the first airflow space SP1 (or gap) between the first extension piece H1 and the second extension piece H2 may correspond to the opening 107a of the lower shell 107 (the opening 107a is shown in FIG. 1B), so that the airflow flows through the airflow space to flow out of the lower shell 107 from the opening 107a by the shortest path. Similarly, the second airflow space SP2 (or gap) between the second extension piece H2 and the third extension piece H3 may correspond to the opening 107a of the lower shell 107 (the opening 107a is shown in FIG. 1B), so that the airflow flows through the airflow space to flow out of the lower shell 107 from the opening 107a by the shortest path. The opening 107a is, for example, a through hole.

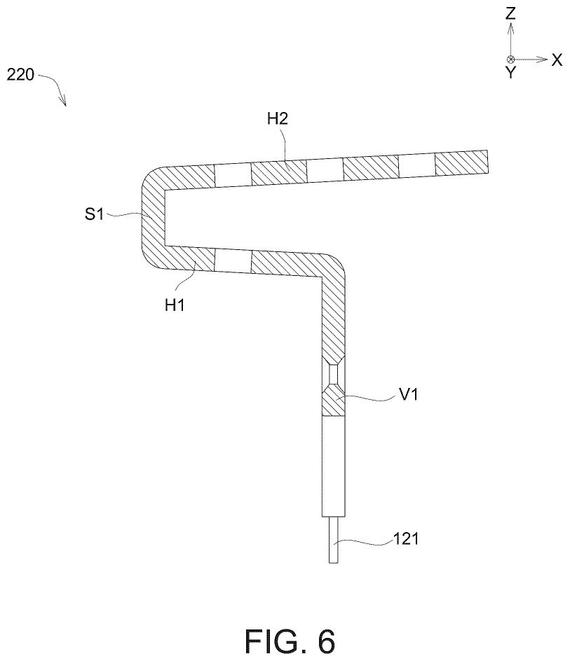

Referring to FIG. 6, FIG. 6 shows a schematic diagram of a heat dissipation component 220 according to another embodiment of the present invention. The heat dissipation component 120 of the electronic device 100 may be replaced by the heat dissipation component 220.

As shown in FIG. 6, the heat dissipation component 220 includes the technical features the same as or similar to that of the aforementioned heat dissipation component 120, and at least one difference is that the number of extension pieces of the heat dissipation component 220 is two (that is, the first extension piece H1 and the second extension piece H1), and the number of connection segments is 1 (that is, the first connection segment S1), wherein the topmost extension piece has a free end. In addition, the material, manufacturing method and/or structure of the heat dissipation component 220 are similar to or the same as that of the heat dissipation component 120, and it will not be repeated here.

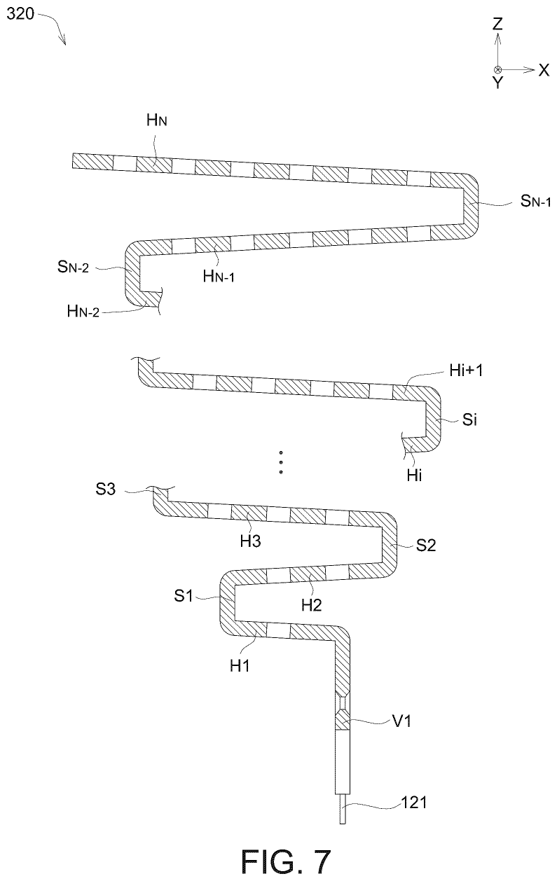

Referring to FIG. 7, FIG. 7 shows a schematic diagram of a heat dissipation component 320 according to another embodiment of the present invention. The heat dissipation component 120 of the electronic device 100 may be replaced by the heat dissipation component 320.

As shown in FIG. 7, the heat dissipation component 320 includes a support segment and N extension pieces. The extension pieces are, for example, transverse segments extending toward a side of the support segment, wherein N is a positive integer equal to or greater than 1, for example, 2, 3, 4, 5, 10, 15, 20 or more, or other odd number or even number. The greater the value of N is, the higher the heat dissipation effect, but the worse the manufacturability is. In an embodiment, the value of N may range between 3 and 5, which may take into account the effects of the heat dissipation effect and the manufacturability. In an embodiment, the N extension pieces are directly connected or indirectly connected in a meandering shape. The first extension piece H1 is directly or indirectly connected to the second extension piece H2. In an embodiment, the first end of the first extension piece is connected to the support segment, and the second end of the first extension piece is connected to the first end of the second extension piece. When i≥2, the first end of the (i+1)^{th} extension piece is directly or indirectly connected to the second end of the i^{th} extension piece, the second end of the (i+1)^{th} extension piece is directly or indirectly connected to the first end of the (i+2)^{th} extension piece, and the Nth extension piece (that is, the last segment or the topmost extension piece) has a free end. In other embodiments, the heat dissipation component 320 further includes N−1 connection segments, wherein the i^{th} connection segment Si connects the i^{th} extension piece with the (i+1)^{th} extension piece, wherein i is a positive integer ranging between 1 and N. In addition, the i^{th} extension piece and the (i+1)^{th} extension piece are non-parallel to each other. For example, there is an included angle between the i^{th} extension piece and the (i+1)^{th} extension piece, wherein the included angle may be an obtuse angle, a right angle or an acute angle. In addition, the material, manufacturing method and/or structure of the heat dissipation component 320 are similar to that of the heat dissipation component 120, and it will not be repeated here. In the present embodiment, the width of the (i+1)^{th} extension piece in X-axis is greater than the width of the i^{th} extension piece in X-axis. However, in another embodiment, the width of the (i+1)^{th} extension piece in X-axis may be substantially equal to the width of the i^{th} extension piece in X-axis. In addition, the material and/or manufacturing method of the heat dissipation component 320 is similar to or the same as that of the heat dissipation component 120, and it will not be repeated here.

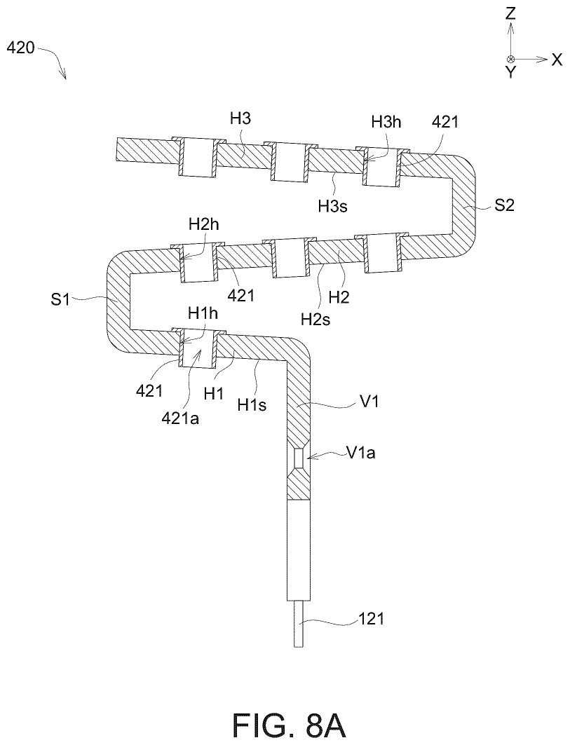

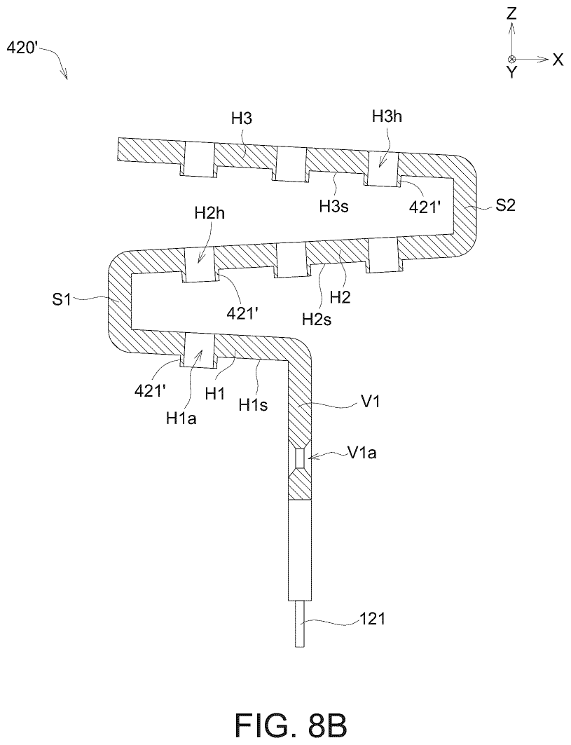

Referring to FIG. 8A, FIG. 8A shows a schematic diagram of a heat dissipation component 420 according to another embodiment of the present invention. The heat dissipation component 120 of the electronic device 100 or 200 may be replaced by the heat dissipation component 420. The heat dissipation component 420 includes the technical features the same as or similar to that of the aforementioned heat dissipation component 120, and at least one difference is that the heat dissipation component 420 further includes at least one guide portion 421, and the guide portion 421 may be disposed on any extension piece. The guide portion 421 disposed on the first extension piece H1 may protrude toward the electronic component. In an embodiment, each guide portion 421 may be disposed on (for example, inserted into) a corresponding through hole (for example, H1h, H2h or H3h). The guide portion 421 has a flow-guide through hole 421a. By the flow-guide through hole 421a, more airflow may be guided to the support segment V1, the first electronic component 140 (not shown) and the second electronic component 150 (not shown). In addition, the guide portion 421 protrudes relative to the lower surface of the extension piece. For example, the guide portion 421 disposed in the through hole H1h of the first extension piece H1 protrudes relative to the lower surface H1s of the first extension piece H1, the guide portion 421 disposed in the through hole H2h of the second extension piece H2 protrudes relative to the lower surface H2s of the second extension piece H2, and the guide portion 421 disposed in the through hole H3h of the second extension piece H3 protrudes relative to the lower surface H3s of the second extension piece H3, so that the airflow path meets an expected design for increasing more airflow to be guided to the support segment V1, the first electronic component 140 (not shown) and the second electronic component 150 (not shown). In addition, due to the guide portion 421 protruding relative to the lower surface of the extension piece, a contact area between the guide portion 421 (or the heat dissipation component 420) and the airflow is increased, thereby improving the heat dissipation effect.

In addition, the material and/or manufacturing method of the heat dissipation component 420 is similar to or the same as that of the heat dissipation component 120, and it will not be repeated here. In addition, the heat dissipation component in other embodiments of the present invention may further include at least one guide portion 421, the configuration of which is the same as that of the aforementioned heat dissipation component 420, and it will not be repeated here.

Referring to FIG. 8B, FIG. 8B shows a schematic diagram of a heat dissipation component 420′ according to another embodiment of the present invention. The heat dissipation component 120 of the aforementioned electronic device 100 or 200 may be replaced by the heat dissipation component 420′. The heat dissipation component 420′ includes the technical features the same as or similar to that of the aforementioned heat dissipation component 420, and at least one difference is that the guide portion 421′ of the heat dissipation component 420′ is an integrally formed structure. In a manufacturing process, for example, at least one through hole (for example, H1h, H2h, H3h, etc.) and a guide portion 421′ are formed in a plate (not shown) by, for example, punching technology, wherein the guide portion 421′ is formed by an extruded plate material when the through hole is formed; then, the bent shape of the heat dissipation component 420′ is formed by, for example, bending or stamping. In addition, due to the guide portion 421′ protruding relative to the lower surface of the extension piece, the contact area between the guide portion 421′ (or the heat dissipation component 420′) and the airflow is increased, thereby improving the heat dissipation effect.

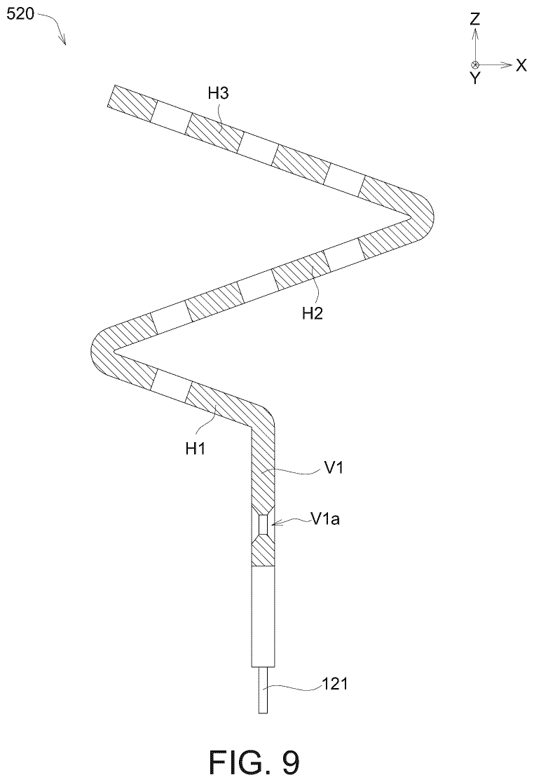

Referring to FIG. 9, FIG. 9 shows a schematic diagram of a heat dissipation component 520 according to another embodiment of the present invention. The heat dissipation component 120 of the aforementioned electronic device 100 or 200 may be replaced by the heat dissipation component 520. The heat dissipation component 520 includes the technical features the same as or similar to that of the aforementioned heat dissipation component 120, and at least one difference is that the heat dissipation component 520 may omit connection segments (for example, the first connection segment S1 and/or the second connection segment S2), and two adjacent extension pieces may be directly connected. For example, the first extension piece H1 and the second extension piece H2 may be directly connected, and the second extension piece H2 and the third extension piece H3 may be directly connected. In addition, the material and/or manufacturing method of the heat dissipation component 520 is similar to or the same as that of the heat dissipation component 120, and it will not be repeated here. In other embodiments, the connection between the first extension piece H1 and the support segment V1 is not limited to the end of the support segment V1 shown in FIG. 9, and the connection between the second extension piece H2 and the first extension piece H1 is also not limited to the end of the first extension piece H1 shown in FIG. 9, as long as the first extension piece H1 or the second extension piece H2 is located above the electronic component.

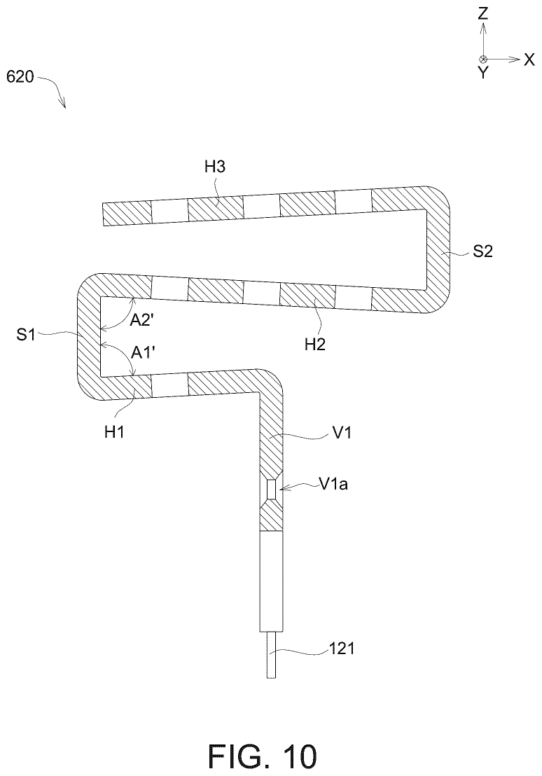

Referring to FIG. 10, FIG. 10 shows a schematic diagram of a heat dissipation component 620 according to another embodiment of the present invention. The heat dissipation component 120 of the electronic device 100 or 200 may be replaced by the heat dissipation component 620. The heat dissipation component 620 includes the technical features the same as or similar to that of the aforementioned heat dissipation component 120, and at least one difference is that an included angle between the connecting extension piece and the connection segment of the heat dissipation component 620 may be an obtuse angle.

For example, an included angle A1′ is included between the first extension piece H1 of the heat dissipation component 620 and the first connection segment S1, and an included angle A2′ is included between the second extension piece H2 and the first connection segment S1, wherein the included angle A1′ and/or the included angle A2′ are, for example, obtuse angles. Alternatively, one of the included angle A1′ and the included angle A2′ is an obtuse angle, and the other of the included angle A1′ and the included angle A2′ may be an acute angle or a right angle. The included angle between the second connection segment S2 and the connected extension piece (that is, the second extension piece H2 and the third extension piece H3) has similar characteristics, and it will not be repeated here.

In addition, the material and/or manufacturing method of the heat dissipation component 620 is similar to or the same as that of the heat dissipation component 120, and it will not be repeated here.

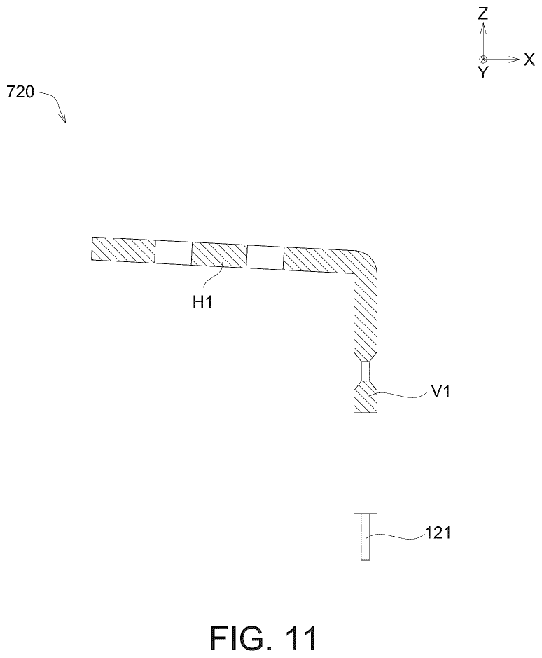

Referring to FIG. 11, FIG. 11 shows a schematic diagram of a heat dissipation component 720 according to another embodiment of the present invention. The heat dissipation component 120 of the aforementioned electronic device 100 or 200 may be replaced by the heat dissipation component 720. The heat dissipation component 720 includes the technical features the same as or similar to that of the aforementioned heat dissipation component 120, and at least one difference is that the number of extension pieces of the heat dissipation component 720 may be single. For example, the heat dissipation component 720 may include the support segment V1 and an extension piece (that is, the first extension piece H1) connected with the support segment V1. In addition, the material and/or manufacturing method of the heat dissipation component 720 is similar to or the same as that of the heat dissipation component 120, and it will not be repeated here.

While the invention has been described by way of example and in terms of the preferred embodiment(s), it is to be understood that the invention is not limited thereto. Based on the technical features embodiments of the present invention, a person ordinarily skilled in the art will be able to make various modifications and similar arrangements and procedures without breaching the spirit and scope of protection of the invention. Therefore, the scope of protection of the present invention should be accorded with what is defined in the appended claims.

What is claimed is:

1. An electronic device, comprising:
a circuit board;
a heat dissipation component disposed on the circuit board and comprising:
a support segment; and
a first extension piece connected to the support segment; and
an electronic component disposed on the support segment;
wherein the first extension piece and the support segment are not parallel.

2. The electronic device according to claim 1, wherein the first extension piece is connected to an end of the support segment and covers the electronic component.

3. The electronic device according to claim 1, wherein the first extension piece has a through hole at a position corresponding to the electronic component.

4. The electronic device according to claim 1, further comprising:
a guide portion disposed on the first extension piece and protruding toward the electronic component.

5. The electronic device according to claim 1, wherein the first extension piece has a first end and a second end, the first end of the first extension piece is connected to an end of the support segment, and the first extension piece extends toward a first side of the support segment, and the heat dissipation component further comprises:
a second extension piece having a first end, wherein the first end of the second extension piece is connected to the second end of the first extension piece, the second extension piece extends toward a second side of the support segment opposite to the first side.

6. The electronic device according to claim 1, wherein the heat dissipation component further comprises:
a second extension piece having a portion facing the first extension piece; and
a connection segment connecting the first extension piece with the second extension piece.

7. The electronic device according to claim 1, further comprising:
a cooling assembly overlapping the support segment or the first extension piece in a direction.

8. The electronic device according to claim 1, wherein the heat dissipation component further comprises:
a second extension piece connected to the first extension piece and having a lower surface facing an upper surface of the first extension piece;
wherein a gap is formed between the upper surface of the first extension piece and the lower surface of the second extension piece.

9. The electronic device according to claim 1, comprising:
a casing having an opening, wherein the circuit board is disposed in the casing;
wherein the heat dissipation component is disposed at a position corresponding to the opening, and the first extension piece has an extension width greater than or equal to a width of the electronic component.

10. The electronic device according to claim 9, wherein the first extension piece has a through hole corresponding to the opening of the casing.

11. The electronic device according to claim 9, wherein the heat dissipation component further comprises:
a second extension piece connected to the first extension piece with a gap formed therebetween at a position corresponding to the opening;
wherein the first extension piece extends toward a side of the support segment, and the second extension piece extends from the first extension piece toward another side of the support segment.

12. The electronic device according to claim 9, wherein the heat dissipation component has a first height, the casing has a second height, and a ratio of the first height to the second height ranges between 0.3 and 0.85.

13. A heat dissipation component, comprising:
a support segment;
a first extension piece having a first end and a second end, wherein the first end of the first extension piece is connected to the support segment; and
a second extension piece having a first end and a second end, wherein the first end of the second extension piece is connected to the second end of the first extension piece, an extension direction of the first end of the first extension piece toward the second end of the first extension piece is different from an extension direction of the first end of the second extension piece toward the second end of the second extension piece.

14. The heat dissipation component according to claim 13, further comprising:
a first connection segment having a first connection end and a second connection end, wherein the first connection end is connected to the second end of the first extension piece, and the second connection end is connected to the first end of the second extension piece.

15. The heat dissipation component according to claim 13, wherein the first extension piece and the second extension piece are disposed oppositely.

16. The heat dissipation component according to claim 13, wherein the heat dissipation component further comprises:
a third extension piece connected to the second end of the second extension piece, wherein the third extension piece is disposed opposite to the second extension piece.

17. The heat dissipation component according to claim 13, wherein at least one of the first extension piece and the second extension piece has at least one through hole.

18. The heat dissipation component according to claim 17, further comprising:
at least one guide portion respectively disposed corresponding to the at least one through hole and protruding toward the support segment.

19. An electronic device, comprising:
a casing having an opening;
a circuit board disposed in the casing;
a heat dissipation component, disposed on the circuit board, corresponding to the opening, and comprising:
a support segment protruding from the circuit board;
a first extension piece having a first end and a second end, wherein the first end of the first extension piece is connected to the support segment; and
a second extension piece having a first end and a second end, wherein the first end of the second extension piece is connected to the second end of the first extension piece, an extension direction of the first end of the first extension piece toward the second end of the first extension piece is different from an extension direction of the first end of the second extension piece toward the second end of the second extension piece; and
an electronic component engaged with the support segment and electrically connected to the circuit board.

20. The electronic device according to claim 19, wherein the second extension piece covers the electronic component, an extension width of the first extension piece is greater than or equal to a width of the electronic component, and an extension width of the second extension piece is greater than the extension width of the first extension piece.
